(19) United States
(12) Patent Application Publication
(10) Pub. No.: US 2025/0231249 A1
(43) Pub. Date: Jul. 17, 2025

(54) METHOD FOR CONTROLLING BATTERY POWER INTERFACE CONVERTER WITH ULTRA-WIDEBAND EIS MEASUREMENT FUNCTION

(71) Applicant: Southwest Jiaotong University, Chengdu (CN)

(72) Inventors: Jin SHA, Chengdu (CN); Gaofeng QIU, Chengdu (CN); Yuebing SUN, Chengdu (CN); Jinsong SHEN, Chengdu (CN); Haitao HU, Chengdu (CN); Zhaoyang ZHAO, Chengdu (CN); Anqi GENG, Chengdu (CN)

(73) Assignee: Southwest Jiaotong University, Chengdu (CN)

(21) Appl. No.: 18/423,000

(22) Filed: Jan. 25, 2024

(30) Foreign Application Priority Data
Nov. 14, 2023 (CN) 2023115133452

(51) Int. Cl. G01R 31/389; H02J 3/10; H02J 7/00

(52) U.S. Cl. CPC G01R 31/389; H02J 3/10; H02J 7/00711

(57) ABSTRACT

The present disclosure is a method for controlling a battery power interface converter with an ultra-wideband EIS measurement function. According to the present disclosure, a discrete pulse control method based on discrete pulse modulation is adopted, which, by generating two discrete duty ratio signals and according to a relationship between a battery charging current and a reference current, selects an appropriate duty ratio signal from the two discrete duty ratio signals to generate a control pulse signal to act on the battery power interface converter. The method of the present disclosure achieves accurate tracking of the output current of the power interface converter to DC charging or ultra-wideband hybrid reference current. A battery charging control system can achieve a normal constant-current charging function while operating in a constant-current charging mode and the ultra-wideband EIS of a battery accurate measurement function in an EIS measurement mode.

### CROSS-REFERENCE TO RELATED APPLICATIONS

The application claims priority to Chinese patent application No. 2023115133452, filed on Nov. 14, 2023, the entire contents of which are incorporated herein by reference.

### TECHNICAL FIELD

The present disclosure relates to the technical field of power electronics, and more particularly, to a method for controlling a battery power interface converter with an ultra-wideband EIS measurement function.

### BACKGROUND

Electrochemical batteries are becoming increasingly important in a variety of applications such as portable electronic devices, electric vehicles, commercial renewable energy systems and smart grids, as the level of science and technology continues to improve and the demand for energy in society grows. Therefore, the diagnosis of the battery lifetime and safety has become a key issue in the field of battery applications. Electrochemical impedance spectroscopy (EIS) is one of the most commonly used methods for battery state assessment and diagnosis. In this method, EIS is obtained by measuring AC complex impedance values of the battery within a certain frequency range, which serves to reflect the electrochemical process in the battery, and hereby to evaluate performance indicators of the battery, such as temperature, state of charge, state of health, etc. Therefore, it is of great significance to study the measurement of the EIS of the battery.

In a laboratory, additional instrumentation equipment is often used to measure the EIS of the battery, and such external measurement devices are bulky and expensive, and need to be operated in an offline testing environment, resulting in inconvenient measurement and the inability to measure the EIS online in real time. Therefore, a simple, low-cost solution that can implement online real-time EIS measurement needs to be designed. Therefore, a battery power interface converter is used to generate an AC disturbance which is superimposed on the dc charging current of the battery, and finally the EIS of the battery is calculated based on the AC components of its current and voltage, thereby achieving embedded battery EIS measurement. That is, the EIS of the battery can be measured online while the battery is charged. This embedded EIS measurement method requires the battery power interface converter to accurately track a hybrid signal composed of a DC charging current signal and tiny wideband AC disturbance signals, which challenges a control technology for the battery power interface converter. Therefore, it is important to investigate a suitable control technology and apply it to the battery power interface converter.

At present, the control technologies applied to the battery interface converter include proportional-integral (PI) control, proportional-integral-resonance (PI-R) control, modeling predicative control (MPC), etc. Traditional PI control has the problem of bandwidth limitation, and fails to track and control high-frequency disturbance signals. Although PI-R control improves the tracking accuracy of a specific disturbance signal by achieving a large gain around the resonance frequency spectrum, it still cannot track the disturbance signals in a wide frequency range. MPC control, on the other hand, has shortcomings such as complex control implementation and substantial computational requirements, and the tracking effect of high-frequency disturbed signals is not ideal. In summary, the existing control technology cannot accurately track and control an ultra-wideband disturbance signal, so that the ultra-wideband EIS accurate measurement cannot be achieved.

In the prior art, the Chinese patent CN115061057A is entitled “Embedded Lithium Battery Impedance Measurement Method and Apparatus Based on Discrete Phase Shift Modulation”. However, the control technique proposed in the present disclosure does not perform accurate interference compensation on a phase-shift duty-ratio signal. That is, the given disturbance phase shift duty ratio signal fails to accurately match the influence of an AC disturbance signal on the phase shift duty ratio, resulting in its unsatisfactory tracking effect on an ultra-wideband AC disturbance signal, and the failure to accurately acquire the ultra-wideband EIS of a battery.

The literature “Model Predictive Control for Electrochemical Impedance Spectroscopy Measurement of Fuel Cells Based on Neural Network Optimization” proposes an EIS measurement apparatus based on a model predictive control method. However, this apparatus suffers from complex control implementation and huge computational cost, and cannot accurately track an ultra-wideband AC interference signal, and thus cannot enable ultra-wideband EIS measurements.

### SUMMARY

In view of the technical issues present in the prior art, the present disclosure proposes a method to control a battery-power interface converter with an ultra-wideband EIS measurement function. In this method, the battery EIS measurement function is embedded in a battery charging control system based on the battery power interface converter to implement the online and real-time accurate measurements of the ultra-wideband EIS of a battery. The battery charging control system achieves a normal constant-current charging function while operating in a constant-current charging mode, and can accurately track an ultra-wideband hybrid reference current while operating in an EIS measurement mode, thereby achieving accurate EIS measurements within the ultra-wide band.

Since the method for controlling the battery charging power interface converter with the ultra-wideband EIS measurement function proposed in the present disclosure does not require linear links such as an error comparator, and can implement the measurement of ultra-wideband EIS when a switching frequency is high enough.

The EIS measurement function is embedded in a battery charging control system based on a battery-power interface converter according to the method of controlling the battery-power interface converter with ultra-wideband EIS measurement functions. The battery charging control system includes a battery power interface converter, a sampling module, a charging control module, an EIS measurement module, and a driving circuit;
the battery power interface converter adopts a DC-DC converter topology;
the sampling module samples an output current i_{bat} and an output voltage u_{bat} of the battery power interface converter, wherein the output current and output voltage of the battery power interface converter are the battery charging current and the battery charging voltage;
the charging control module includes an operating mode determination circuit, an output current comparator, a duty ratio generator, a duty ratio selector and a PWM circuit;
the operating mode determination circuit determines whether the battery charging control system operates in a constant-current charging mode or in an EIS measurement mode according to the output current i_{bat} and the output voltage u_{bat} of the battery power interface converter;
the output current comparator compares the output current i_{bat} sampled by the current sampling circuit with the output reference current i_{ref} to output a comparison signal v_{c}, and inputs the comparison signal v_{c} into the duty ratio selector;
the duty ratio generator generates two discrete duty ratio signals d_{H} and d_{L} according to the output voltage u_{bat} sampled by the voltage sampling circuit, an output signal of the operating mode determination circuit and a discrete duty ratio function, and inputs the two discrete duty ratio signals d_{H} and d_{L} into the duty ratio selector;
in the constant-current charging mode, the discrete duty ratio function is:
d_{H}=K_{H}d_{dc}, d_{L}=K_{L}d_{dc};
in the EIS measurement mode, the discrete duty ratio function is:

$${d}_{H} = {K}_{H} {d}_{dc} + {d}_{ac} , {d}_{L} = {K}_{L} {d}_{dc} + {d}_{ac} ;$$

wherein, d_{dc}=f(Uᵢₙ, u_{bat}, R), d_{ac}=f(Uᵢₙ, i_{ref_ac}, Z)
in which, K_{H} and K_{L} are two preset constant discrete control parameters; d_{dc} and d_{ac} are a DC duty ratio function and an AC disturbance duty ratio function in a corresponding target duty ratio function, respectively, when the output current i_{bat} of the battery power interface converter accurately tracks a hybrid reference current I_{ref_dc}+i_{ref_ac}; Uᵢₙ is an input voltage of the battery power interface converter; u_{bat} is an output voltage of the battery power interface converter; i_{ref_ac} is a sinusoidal AC disturbance reference current; R is a circuit parameter set related to the DC duty ratio function d_{dc} in the battery power interface converter; and Z is a circuit parameter set related to the AC disturbance duty ratio function d_{ac} in the battery power interface converter;
the duty ratio selector selects one of the two discrete duty ratio signals d_{H} and d_{L} as an effective duty ratio signal dₐ outputted by the duty ratio selector according to the comparison signal v_{c}, and inputs the effective duty ratio signal dₐ into the PWM circuit;
the PWM circuit generates a control pulse signal vₚ₁ of the power switching device of the battery power interface converter according to the effective duty ratio signal dₐ outputted by the duty ratio selector, and inputs the control pulse signal vₚ₁ into the driving circuit;
the driving circuit generates a driving signal v₁ of the power switching device of the battery power interface converter according to the control pulse signal vₚ₁ outputted by the PWM circuit.

Preferably, the EIS measurement module includes an FFT analysis sub-module and an EIS calculation sub-module, and the sampling module includes a current sampling circuit and a voltage sampling circuit.

Preferably, the FFT analysis sub-module is configured to perform FFT analysis on u_{bat} and i_{bat} sampled by the voltage sampling circuit and the current sampling circuit to obtain a voltage amplitude |u_{bat(ac)}|, a current amplitude |i_{bat(ac)}|, a voltage phase φᵤ and a current phase φᵢ of their AC components at a frequency of the sinusoidal AC disturbance reference current i_{ref_ac};
the EIS calculation sub-module calculates an impedance value of a battery at the frequency of the sinusoidal AC disturbance reference current i_{ref_ac} according to the amplitude and phase information and functions |Z_{bat}|=|u_{bat(ac)}|/|i_{bat(ac)}| and φ_{Z}=φᵤ−φᵢ outputted from the FFT analysis sub-module,
in which, |Z_{bat}| is an impedance modulus of a battery impedance, and φ_{Z} is an impedance angle of the battery impedance.

Preferably, the current sampling circuit samples the output current i_{bat} of the battery power interface converter and outputs the output current to the operating mode determination circuit, the FFT analysis sub-module and the output current comparator; and
the voltage sampling circuit samples the output voltage u_{bat} of the battery power interface converter and outputs the output voltage to the operating mode determination circuit, the duty ratio generator and the FFT analysis sub-module.

Preferably, a specific method for the operating mode determination circuit to determine whether the battery charging control system operates in the constant-current charging mode or in the EIS measurement mode according to the output current i_{bat} and the output voltage u_{bat} of the battery power interface converter includes:
determining whether they are in a DC steady state according to the output current i_{bat} and the output voltage u_{bat} of the battery power interface converter;
if so, determining that the battery charging control system operates in the constant-current charging mode; and
if not, determining whether the ripple peak-to-peak value of the output current i_{bat} is stabilized at a set value, wherein the set value is greater than a peak-to-peak value of the injected sinusoidal AC perturbation reference current i_{ref_ac}; if so, determining that the battery charging control system operates in the EIS measurement mode; and if not, determining that the battery charging control system continues to operate in the constant-current charging mode.

Preferably, the constant-current charging mode and the EIS measurement mode are operated in the following ways:
in the constant-current charging mode, the output reference current i_{ref} of the battery power interface converter is equal to a DC charging reference current I_{ref_dc} of the battery power interface converter, the AC disturbance duty ratio function d_{ac} in the duty ratio generator stops outputting, and the EIS measurement module stops operating; and
in the EIS measurement mode, the output reference current i_{ref} of the battery power interface converter is equal to the hybrid reference current I_{ref_dc}+i_{ref_ac} of the battery power interface converter, the AC disturbance duty ratio function d_{ac} in the duty ratio generator is normally outputted, and the EIS measurement module starts operating.

Preferably, a specific method for the duty ratio selector to select one of the two discrete duty ratio signals d_{H} and d_{L} as an effective duty ratio signal dₐ outputted by the duty ratio selector according to the comparison signal v_{c} includes:
if i_{bat}<i_{ref}, selecting the discrete duty ratio signal d_{H} as an effective duty ratio signal dₐ of the current switching cycle, such that the output current of the battery power interface converter rises; and if i_{bat}≥i_{ref}, selecting the discrete duty ratio signal d_{L} as the effective duty ratio signal dₐ of the current switching cycle, such that the output current of the battery power interface converter drops.

Preferably, when the battery charging control system operate in the constant-current charging mode, the output current i_{bat} of the battery power interface converter can accurately track the DC charging reference current I_{ref_dc}; and when the battery charging control system operates in the EIS measurement mode, the output current i_{bat} of the battery power interface converter can accurately track the hybrid reference current I_{ref_dc}+i_{ref_ac}, the hybrid reference current being composed of the DC charging reference current I_{ref_dc} superimposed on the sinusoidal AC disturbance reference current i_{ref_ac}.

The present disclosure has the following beneficial effects.

(1) The battery EIS measurement function is embedded in the battery charging control system to implement the online and real-time accurate measurement of the ultra-wideband EIS of the battery.

(2) A discrete control pulse duty ratio is generated by constructing a target duty ratio function of a reference current, so as to realize accurate tracking of various types of ultra-wideband hybrid reference currents, and then to realize real-time accurate measurement of the ultra-wideband EIS while the battery is controlled to be charged.

(3) The method of the present disclosure has the advantages of simple implementation, low cost, simple and easy control technique, EIS online measurements, ultra-wideband EIS, system stability, strong anti-interference ability, and the like.

### BRIEF DESCRIPTION OF DRAWINGS

FIG. 1 is a schematic structural diagram of the present disclosure;

FIG. 2 is a schematic structural diagram of an embodiment of the present disclosure;

FIG. 3 is a simulated waveform diagram of an output current i_{bat} of a buck-boost converter and its hybrid reference current I_{ref_dc}+i_{ref_ac} when a battery charging control system in an embodiment of the present disclosure adopts a traditional PI control method and operates in an EIS measurement mode; and

FIG. 4 is a simulated waveform diagram of an output current i_{bat} of a buck-boost converter and its hybrid reference current I_{ref_dc}+i_{ref_ac} when a battery charging control system in an embodiment of the present disclosure adopts a control method of the present disclosure and operates in an EIS measurement mode.

### DETAILED DESCRIPTION OF THE EMBODIMENTS

In order to make the objectives, technical solutions, and advantages of the present application clearer, the following further describes the present application in detail with reference to the accompanying drawings and the embodiments.

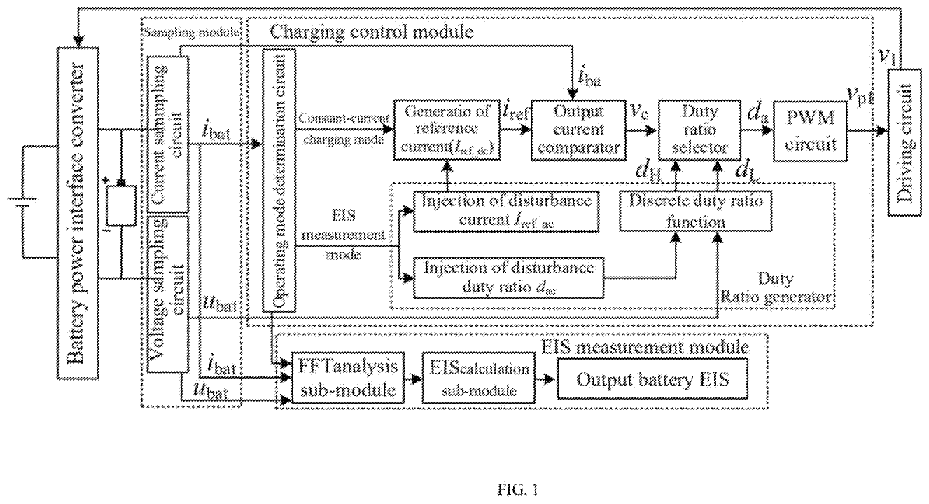

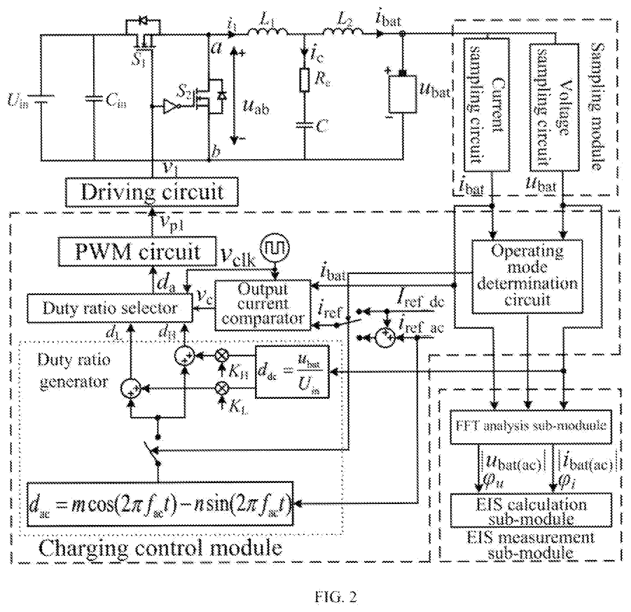

As shown in FIG. 1 to FIG. 2, a battery charging apparatus using a method for controlling a battery power interface converter with an ultra-wideband EIS measurement function is provided. The EIS measurement function is embedded in a battery charging control system based on the battery power interface converter. The battery charging control system consists of a battery power interface converter, a sampling module, a charging control module, an EIS measurement module, and a driving circuit;
the battery power interface converter in the present embodiment adopts a buck-boost converter topology to further elaborate the present disclosure;
the sampling module samples an output current i_{bat} and an output voltage u_{bat} of the buck-boost converter, wherein the output current and output voltage of the battery power interface converter are the battery charging current and the battery charging voltage;
the charging control module includes an operating mode determination circuit, an output current comparator, a duty ratio generator, a duty ratio selector and a PWM circuit;
the operating mode determination circuit determines whether the battery charging control system operates in a constant-current charging mode or in an EIS measurement mode according to the output current i_{bat} and the output voltage u_{bat} of the buck-boost converter;
the output current comparator compares the output current i_{bat} sampled by the current sampling circuit with the output reference current i_{ref} to output a comparison signal v_{c}, and inputs the comparison signal v_{c} into the duty ratio selector;
the duty ratio generator generates two discrete duty ratio signals d_{H} and d_{L} according to the output voltage u_{bat} sampled by the voltage sampling circuit, an output signal of the operating mode determination circuit and a discrete duty ratio function, and inputs the two discrete duty ratio signals d_{H} and d_{L} into the duty ratio selector;
in the constant-current charging mode, the discrete duty ratio function is:
d_{H}=K_{H}d_{dc}, d_{L}=K_{L}d_{dc};
in the EIS measurement mode, the discrete duty ratio function is:

$${d}_{H} = {K}_{H} {d}_{dc} + {d}_{ac} , {d}_{L} = {K}_{L} {d}_{dc} + {d}_{ac} ; \\ wherein {d}_{dc} = \frac{{u}_{bat}}{{U}_{in}} , {d}_{ac} = m cos ( 2 π {f}_{ac} t ) - n sin ( 2 π {f}_{ac} t ) ; \\ m = \frac{2 π {f}_{ac} ( {L}_{1} + {L}_{2} ) {I}_{ac}}{{U}_{in}} - \frac{8 {π}^{3} {f}_{ac}^{3} {L}_{1} {L}_{2} {CI}_{ac}}{( 1 + 4 {π}^{2} {f}_{ac}^{2} {R}_{c}^{2} {C}^{2} ) {U}_{in}} ; \\ n = \frac{16 {π}^{4} {f}_{ac}^{4} {L}_{1} {L}_{2} {R}_{c} {C}^{2} {I}_{ac}}{( 1 + 4 {π}^{2} {f}_{ac}^{2} {R}_{C}^{2} {C}^{2} ) {U}_{in}} ;$$

in which, K_{H} and K_{L} are two preset constant discrete control parameters; d_{dc} and d_{ac} are a DC duty ratio function and an AC disturbance duty ratio function in a corresponding target duty ratio function, respectively when the output current i_{bat} of the buck-boost converter accurately tracks a hybrid reference current I_{ref_dc}+i_{ref_ac}; Uᵢₙ is an input voltage of the buck-boost converter; u_{bat} is an output voltage of the battery power interface converter; I_{ac} is an amplitude of the sinusoidal AC disturbance reference current i_{ref_ac}; and f_{ac} is a frequency of the sinusoidal AC disturbance reference current i_{ref_ac}; m is a cosine coefficient that changes with a frequency f_{ac}; n is a sine coefficient that changes with the frequency f_{ac}. At this time, the circuit parameter set R related to the DC duty cycle function d_{dc} in buck-boost converter is zero; The circuit parameter set Z associated with the AC duty cycle function d_{ac} in the buck-boost converter includes the input inductance L₁ of the buck-boost converter, the output inductance L₂ of the buck-boost converter, the output capacitance C of the buck-boost converter, and the equivalent capacitance equivalent series resistance R_{c} on the output side of the buck-boost converter.
the duty ratio selector is configured to select one of the two discrete duty ratio signals d_{H} and d_{L} as an effective duty ratio signal da outputted by the duty ratio selector according to the comparison signal v_{c}, and inputs the effective duty ratio signal da into the PWM circuit;
the PWM circuit generates a control pulse signal vₚ₁ of the power switching device of the buck-boost converter according to the effective duty ratio signal dₐ outputted by the duty ratio selector, and inputs the control pulse signal vₚ₁ into the driving circuit;
the driving circuit generates a driving signal v₁ of the power switching device of the buck-boost converter according to the control pulse signal vₚ₁ outputted by the PWM circuit.

The battery charging control system includes two operating modes: a constant-current charging mode and an EIS measurement mode; and
when the battery charging control system operates in the constant-current charging mode, the DC duty ratio function d_{dc} is constructed according to the DC charging reference current I_{ref_dc}. Two sets of discrete duty ratio signals d_{H} and d_{L} are designed in advance according to the DC duty ratio function d_{dc}, where d_{H}=K_{H}d_{dc}, d_{L}=K_{L}d_{dc}.

At the beginning of each switching cycle Tₛ, the output current i_{bat} of the buck-boost converter is sampled by the current sampling circuit, and the output current comparator compares the output current i_{bat} of the buck-boost converter with the DC charging reference current I_{ref_dc}. According to the comparison result, an appropriate duty ratio signal is selected from the two discrete duty ratio signals d_{H} and d_{L} as an effective duty ratio signal dₐ of the current switching cycle. In addition, a control pulse signal vₚ₁ of a power switching device of the buck-boost converter is generated according to the effective duty ratio signal dₐ. In a case of i_{bat}<I_{ref_dc} and the effective duty ratio signal dₐ=d_{H}, a controller allows an output current of the buck-boost converter to rise by outputting a larger duty ratio; and in a case of i_{bat}≥I_{ref_dc} and the effective duty ratio signal dₐ=d_{L}, the controller allows the output current of the buck-boost converter to drop by outputting a smaller duty ratio.

When the battery charging control system operates in the EIS measurement mode, the controller injects a sinusoidal AC disturbance reference current i_{ref_ac} into the DC charging reference current I_{ref_dc}. At the same time, the AC disturbance duty ratio function d_{ac} which matches the sinusoidal AC disturbance reference current i_{ref_ac} is injected into two sets of discrete duty ratio signals d_{H} and d_{L}. Therefore, the output reference current of the buck-boost converter turns to I_{ref_dc}+i_{ref_ac}, and the two sets of discrete duty ratio signals d_{H} and d_{L} turn to d_{H}=K_{H}d_{dc}+d_{ac} and d_{L}=K_{L}d_{dc}+d_{ac}, respectively.

At the beginning of each switching cycle Tₛ, the output current i_{bat} of the buck-boost converter is sampled by the current sampling circuit, and the output current comparator compares the output current i_{bat} of the buck-boost converter with the hybrid reference current I_{ref_dc}+i_{ref_ac}. According to the comparison result, an appropriate duty ratio signal is selected from the two discrete duty ratio signals d_{H} and d_{L} as an effective duty ratio signal dₐ of the current switching cycle. In addition, a control pulse signal vₚ₁ of a power switching device of the buck-boost converter is generated according to the effective duty ratio signal dₐ. In a case of i_{bat}<I_{ref_dc}+i_{ref_ac} and the effective duty ratio signal dₐ=d_{H}, the controller allows the output current of the buck-boost converter to rise by outputting a larger duty ratio; and in a case of i_{bat}≥I_{ref_dc}+i_{ref_ac} and the effective duty ratio signal dₐ=d_{L}, the controller allows the output current of the buck-boost converter to drop by outputting a smaller duty ratio. The K_{H} and K_{L} are two preset constant discrete control parameters. In order for the resulting effective duty ratio signal dₐ to satisfy 0<dₐ<1, K_{H} and K_{L} need to satisfy:—d_{ac}/d_{dc}<K_{L}<1<K_{H}<(1−d_{ac})/d_{dc}. In the EIS measurement mode, the output current (i.e., battery charging current) of the buck-boost converter can accurately and rapidly fit an ultra-wideband reference current signal in real time. According to the present disclosure, the battery charging current i_{bat} and the battery charging voltage u_{bat} can be sampled, and the results of the ultra-wideband EIS measurements of the battery can be obtained by the FFT analysis sub-module and the EIS computation sub-module.

Time-domain simulated analysis is performed in this embodiment of the present disclosure, wherein the battery power interface converter adopts a buck-boost converter topology structure. The main circuit parameters of the buck-boost converter are: an input voltage, Uᵢₙ=12V; an input side inductance, L₁=100 μH; an output side inductance, L₂=22 μH; a switching frequency, fₛ=500 kHz; an output side filter capacitance, C=470 μF; an equivalent series resistance of the output side filter capacitor, R_{c}=0.5Ω; a nominal voltage of a lithium battery, V_{bat}=3.6V; a DC charging reference current of the lithium battery, I_{ref}=0.975 A; and an amplitude of the sinusoidal AC disturbance reference current, I_{ac}=0.05 A. The simulation results are as follows.

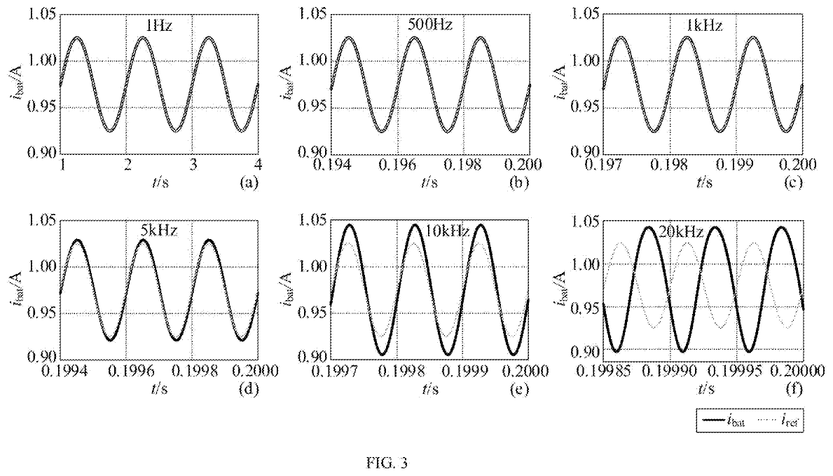

FIG. 3 is a simulated waveform diagram of an output current i_{bat} of a buck-boost converter and its output reference current i_{ref}=I_{ref_dc}+i_{ref_ac} (i.e., the hybrid reference current) when a battery charging control system in an embodiment of the present disclosure adopts a traditional PI control method and operates in an EIS measurement mode. The sinusoidal AC disturbance reference currents corresponding to the respective figures each have an amplitude I_{ac} of 0.05 A, and have the frequencies of: 1 Hz in (a), 500 Hz in (b), 1 kHz in (c), 5 kHz in (d), 10 kHz in (e), and 20 kHz in (f), respectively.

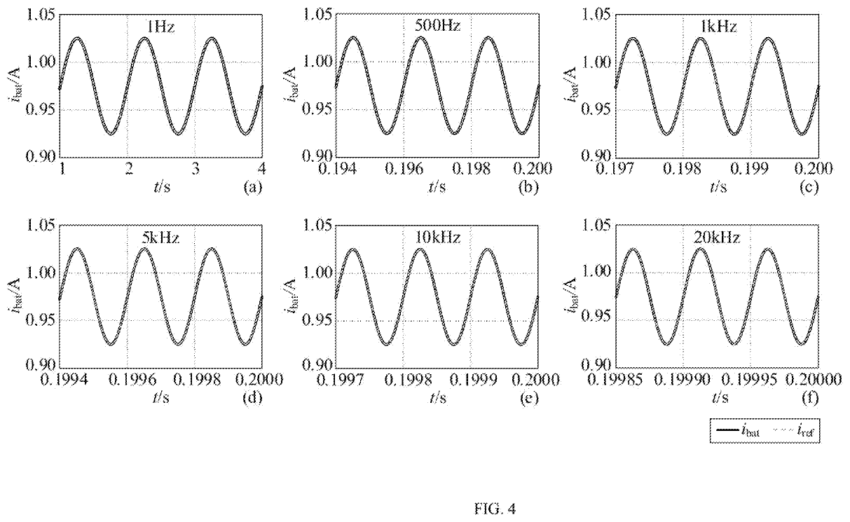

FIG. 4 is a simulated waveform diagram of an output current i_{bat} of a buck-boost converter and its output reference current i_{ref}=I_{ref_dc}+i_{ref_ac} (i.e., the hybrid reference current) when a battery charging control system in an embodiment of the present disclosure adopts the method of the present disclosure and operates in an EIS measurement mode. The sinusoidal AC disturbance reference currents corresponding to the respective figures each have an amplitude I_{ac} of 0.05 A, and have the frequencies of: 1 Hz in (a), 500 Hz in (b), 1 kHz in (c), 5 kHz in (d), 10 kHz in (e), and 20 kHz in (f), respectively.

As can be seen from FIG. (a) to FIG. (f) in FIG. 3 and FIG. (a) to FIG. (f) in FIG. 4, in this embodiment of the present disclosure, when the battery charging control system adopts the traditional PI control method, the output current i_{bat} of the buck-boost converter can accurately track the hybrid reference current I_{ref_dc}+i_{ref_ac} at 1 Hz, 500 Hz and 1 kHz, but cannot accurately track the hybrid reference current I_{ref_dc}+i_{ref_ac} at ultra-wide frequencies of 5 kHz, 10 kHz and 20 kHz; and when the battery charging control system adopts the control method of the present disclosure, the output current i_{bat} of the buck-boost converter can achieve high-precision tracking effects for the hybrid reference current I_{ref_dc}+i_{ref_ac} at 1 Hz, 500 Hz, 1 kHz, 5 kHz, 10 kHz and 20 kHz. This shows that for the battery charging control system, in an ultra-wide band, the effect achieved in response to using the control method of the present disclosure is better than the effect achieved in response to using the traditional PI control method.

In this embodiment of the present disclosure, the buck-boost converter is used as the battery power interface converter. A discrete pulse control method based on discrete pulse modulation is adopted, which, by generating two discrete duty ratio signals and according to a relationship between an output current and a reference current, selects an appropriate duty ratio signal from the two duty ratio signals to generate a control pulse signal of a power switching device of the buck-boost converter and to act on the buck-boost converter. The method of the present disclosure achieves accurate tracking of the output current of the buck-boost converter to the DC charging or hybrid reference current. The battery charging control system can achieve a normal constant-current charging function while operating in the constant-current charging mode, and can accurately track an ultra-wideband hybrid reference current of the output current of the buck-boost converter while operating in the EIS measurement mode, thereby achieving the ultra-wideband EIS accurate measurement of the battery.

The basic principles and main features of the present disclosure and the advantages of the present disclosure have been shown and described above. Those skilled in the art should understand that the present disclosure is not limited by the aforementioned embodiments. The foregoing embodiments and descriptions described in the specification only illustrate the principle of the present disclosure. Without departing from the spirit and scope of the present disclosure, the present disclosure will have various changes and improvements, and these changes and improvements fall into the claimed disclosure. The protection scope of the present disclosure is defined by the appended claims and their equivalents.

What is claimed is:

1. A method for controlling a battery power interface converter with an ultra-wideband EIS measurement function, wherein the battery EIS measurement function is embedded in a charging control system of a battery power interface, the charging control system of the battery power interface comprising the battery power interface converter, a sampling module, a charging control module, an EIS measurement module, and a driving circuit;
the battery power interface converter adopts a DC-DC converter topology;
the sampling module samples an output current i_{bat} and an output voltage u_{bat} of the battery power interface converter, wherein the output current and output voltage of the battery power interface converter are the battery charging current and the battery charging voltage;
the charging control module comprises an operating mode determination circuit, an output current comparator, a duty ratio generator, a duty ratio selector and a PWM circuit;
the operating mode determination circuit determines whether the battery charging control system is operating in a constant-current charging mode or in an EIS measurement mode according to the output current i_{bat} and the output voltage u_{bat} of the battery power interface converter;
the output current comparator compares the output current i_{bat} sampled by the current sampling circuit with the output reference current i_{ref} to output a comparison signal v_{c}, and inputs the comparison signal v_{c} into the duty ratio selector;
the duty ratio generator generates two discrete duty ratio signals d_{H} and d_{L} according to the output voltage u_{bat}, an output signal of the operating mode determination circuit and a discrete duty ratio function, and inputs the two discrete duty ratio signals d_{H} and d_{L} into the duty ratio selector;
in the constant-current charging mode, the discrete duty ratio function is:
d_{H}=K_{H}d_{dc}, d_{L}=K_{L}d_{dc};
in the EIS measurement mode, the discrete duty ratio function is:
$${d}_{H} = {K}_{H} {d}_{dc} + {d}_{ac} , {d}_{L} = {K}_{L} {d}_{dc} + {d}_{ac} ;$$
wherein, d_{dc}=f(Uᵢₙ, u_{bat}, R), d_{ac}=f(Uᵢₙ, i_{ref_ac}, Z);
in which, K_{H} and K_{L} are two preset constant discrete control parameters; d_{dc} and d_{ac} are a DC duty ratio function and an AC disturbance duty ratio function in a corresponding target duty ratio function, respectively, when the output current i_{bat} of the battery power interface converter accurately tracks a hybrid reference current I_{ref_dc}+i_{ref_ac}; Uᵢₙ is an input voltage of the battery power interface converter; u_{bat} is an output voltage of the battery power interface converter; i_{ref_ac} is a sinusoidal AC disturbance reference current; R is a circuit parameter set related to the DC duty ratio function d_{dc} in the battery power interface converter; and Z is a circuit parameter set related to the AC disturbance duty ratio function d_{ac} in the battery power interface converter;
the duty ratio selector selects one of the two discrete duty ratio signals d_{H} and d_{L} as an effective duty ratio signal dₐ outputted by the duty ratio selector according to the comparison signal v_{c}, and inputs the effective duty ratio signal dₐ into the PWM circuit;
the PWM circuit generates a control pulse signal vₚ₁ of the power switching device of the battery power interface converter according to the effective duty ratio signal dₐ, and inputs the control pulse signal vₚ₁ into the driving circuit;
the driving circuit generates a driving signal v₁ of the power switching device of the battery power interface converter according to the control pulse signal vₚ₁.

2. The method for controlling the battery power interface converter with the ultra-wideband EIS measurement function according to claim 1, wherein the EIS measurement module comprises an FFT analysis sub-module and an EIS calculation sub-module, and the sampling module comprises a current sampling circuit and a voltage sampling circuit.

3. The method for controlling the battery power interface converter with the ultra-wideband EIS measurement function according to claim 2, wherein the FFT analysis sub-module is configured to perform FFT analysis on u_{bat} and i_{bat} sampled by the voltage sampling circuit and the current sampling circuit to obtain a voltage amplitude |u_{bat(ac)}|, a current amplitude |i_{bat(ac)}|, a voltage phase φᵤ and a current phase φᵢ of their AC components at a frequency of the sinusoidal AC disturbance reference current i_{ref_ac};
the EIS calculation sub-module calculates an impedance value of a battery at the frequency of the sinusoidal AC disturbance reference current i_{ref_ac} according to the amplitude and phase information and functions |Z_{bat}|=|u_{bat(ac)}|/|i_{bat(ac)}| and φ_{Z}=φᵤ−φᵢ outputted from the FFT analysis sub-module,
in which, |Z_{bat}| is an impedance modulus of a battery impedance, and φ_{Z} is an impedance angle of the battery impedance.

4. The method for controlling the battery power interface converter with the ultra-wideband EIS measurement function according to claim 2, wherein the current sampling circuit samples the output current i_{bat} of the battery power interface converter and outputs the output current to the operating mode determination circuit, the FFT analysis sub-module and the output current comparator; and
the voltage sampling circuit samples the output voltage u_{bat} of the battery power interface converter and outputs the output voltage to the operating mode determination circuit, the duty ratio generator and the FFT analysis sub-module.

5. The method for controlling the battery power interface converter with the ultra-wideband EIS measurement function according to claim 1, wherein a specific method for the operating mode determination circuit to determine whether the battery charging control system operates in the constant-current charging mode or in the EIS measurement mode according to the output current i_{bat} and the output voltage u_{bat} comprises:
determining whether they are in a DC steady state according to the output current i_{bat} and the output voltage u_{bat} of the battery power interface converter;
if so, determining that the battery charging control system operates in the constant-current charging mode; and
if not, determining whether the ripple peak-to-peak value of the output current i_{bat} is stabilized at a set value, wherein the set value is greater than a peak-to-peak value of the injected sinusoidal AC disturbance reference current i_{ref_ac}; if so, determining that the battery charging control system operates in the EIS measurement mode; and if not, determining that the battery charging control system continues to operate in the constant-current charging mode.

6. The method for controlling the battery power interface converter with the ultra-wideband EIS measurement function according to claim 5, wherein the constant-current charging mode and the EIS measurement mode are operated in the following ways:
in the constant-current charging mode, the output reference current i_{ref} of the battery power interface converter is equal to a DC charging reference current I_{ref_dc} of the battery power interface converter, the AC disturbance duty ratio function d_{ac} in the duty ratio generator stops outputting, and the EIS measurement module stops operating; and
in the EIS measurement mode, the output reference current i_{ref} of the battery power interface converter is equal to the hybrid reference current I_{ref_dc}+i_{ref_ac} of the battery power interface converter, the AC disturbance duty ratio function d_{ac} in the duty ratio generator is normally outputted, and the EIS measurement module starts operating.

7. The method for controlling the battery power interface converter with the ultra-wideband EIS measurement function according to claim 1, wherein a specific method for the duty ratio selector to select one of the two discrete duty ratio signals d_{H} and d_{L} as the effective duty ratio signal dₐ outputted by the duty ratio selector according to the comparison signal v_{c} is as follows:
when the battery charging control system operates in the constant-current charging mode, at the beginning of each switching cycle Tₛ, the output current i_{bat} of the battery power interface converter is sampled by the sampling module, and the output current comparator compares the output current i_{bat} of the battery power interface converter with a DC charging reference current I_{ref_dc}; according to a comparison result, an appropriate duty ratio signal is selected from the two discrete duty ratio signals d_{H} and d_{L} as an effective duty ratio signal dₐ of the current switching cycle; a control pulse signal vₚ₁ of the power switching device of the battery power interface converter is generated according to the effective duty ratio signal dₐ; in a case of i_{bat}<I_{ref_dc} and the effective duty ratio signal dₐ=d_{H}, the controller allows the output current of the battery power interface converter to rise by outputting a larger duty ratio signal; in a case of i_{bat}≥I_{ref_dc} and the effective duty ratio signal dₐ=d_{L}, the controller allows the output current of the battery power interface converter to drop by outputting a smaller duty ratio signal;
when the battery charging control system operates in the EIS measurement mode, the controller injects a sinusoidal AC disturbance reference current i_{ref_ac} into the DC charging reference current I_{ref_dc}; at the same time, the AC disturbance duty ratio signal d_{ac} which matches the sinusoidal AC disturbance reference current i_{ref_ac} is injected into the two discrete duty ratio signals d_{H} and d_{L}; accordingly, the output reference current of the battery power interface converter turns to I_{ref_dc}+i_{ref_ac}, and the two discrete duty ratio signals d_{H} and d_{L} turn to d_{H}=K_{H}d_{dc}+d_{ac} and d_{L}=K_{L}d_{dc}+d_{ac}, respectively;
at the beginning of each switching cycle Tₛ, the output current i_{bat} of the battery power interface converter is sampled by the sampling module, and the output current comparator compares the output current i_{bat} of the battery power interface converter with the hybrid reference current I_{ref_dc}+i_{ref_ac}; according to a comparison result, an appropriate duty ratio signal is selected from the two discrete duty ratio signals d_{H} and d_{L} as an effective duty ratio signal dₐ of the current switching cycle; a control pulse signal vₚ₁ of the power switching device of the battery power interface converter is generated according to the effective duty ratio signal dₐ; in a case of i_{bat}<I_{ref_dc}+i_{ref_ac} and the effective duty ratio signal dₐ=d_{H}, the controller allows the output current of the battery power interface converter to rise by outputting a larger duty ratio signal; in a case of i_{bat}≥I_{ref_dc}+i_{ref_ac} and the effective duty ratio signal dₐ=d_{L}, the controller allows the output current of the battery power interface converter to drop by outputting a smaller duty ratio signal; the K_{H} and K_{L} are two preset constant discrete control parameters; and in order for the resulting effective duty ratio signal dₐ to satisfy 0<dₐ<1, K_{H} and K_{L} need to satisfy:
$$- {d}_{ac} / {d}_{dc} < {K}_{L} < 1 < {K}_{H} < ( 1 - {d}_{ac} ) / {d}_{dc} .$$

8. The method for controlling the battery power interface converter with the ultra-wideband EIS measurement function according to claim 1, wherein when the battery charging control system operate in the constant-current charging mode, the output current i_{bat} of the battery power interface converter can accurately track the DC charging reference current I_{ref_dc}; and when the battery charging control system operates in the EIS measurement mode, the output current i_{bat} of the battery power interface converter can accurately track the hybrid reference current I_{ref_dc}+i_{ref_ac}, the hybrid reference current being composed of the DC charging reference current I_{ref_dc} superimposed on the sinusoidal AC disturbance reference current i_{ref_ac}.
